(19) United States
(12) Patent Application Publication
(10) Pub. No.: US 2026/0047028 A1
(43) Pub. Date: Feb. 12, 2026

(54) POWER MODULE AND SERVER

(71) Applicant: Suzhou MetaBrain Intelligent Technology Co., Ltd., Suzhou, Jiangsu (CN)

(72) Inventor: Hui SUN, Suzhou, Jiangsu (CN)

(21) Appl. No.: 19/141,166

(22) PCT Filed: Apr. 12, 2024
(86) PCT No.: PCT/CN2024/087631

§ 371 Date: Jun. 19, 2025

(30) Foreign Application Priority Data
Nov. 30, 2023 (CN) 202311620091.4

(51) Int. Cl. H05K 7/14; H05K 1/02

(52) U.S. Cl. CPC H05K 7/1492; H05K 1/0203; H05K 2201/10409

(57) ABSTRACT

The present application discloses a power module and a server. The power module includes a plurality of power chips, a plurality of input capacitors, a plurality of output inductors, and a first printed circuit board. The plurality of power chips are spaced apart on an upper surface of the first printed circuit board, and input ends of the plurality of power chips are connected to an input power source. The plurality of input capacitors are fixedly arranged at the first printed circuit board. The plurality of output inductors are stacked with the plurality of power chips in a vertical direction through the first printed circuit board. Output ends of the plurality of output inductors are connected to a load in a third printed circuit board to supply power to the load. The plurality of output inductors are located on a lower surface of the third printed circuit board.

### CROSS-REFERENCE TO RELATED APPLICATION

This application claims priority to Chinese Patent Application No. 202311620091.4, filed with China National Intellectual Property Administration on Thursday, Nov. 30, 2023 and entitled “POWER MODULE AND SERVER”, which is incorporated herein by reference in its entirety.

### FIELD

The present application relates to a power module and a server.

### BACKGROUND

A function of a multiphase power source is to convert external direct current input voltage into direct current working voltage of an appropriate level for an execution apparatus of a device such as a server and to achieve stable power supplying, so as to ensure stable operation of the device such as the server. A central processing unit (CPU), as the “brain” of the server, is a primary indicator for measuring performance of the server. With the rise of technologies such as 5G, big data, cloud computing, or artificial intelligence, demands for CPU power continue to increase, and increasing attentions are paid to the problem of increased current loss in a power supplying path of the server.

A traditional CPU power supplying architecture of the server is 12V horizontal power supplying. In some embodiments, by using a mode in which a power chip and an output inductor are separated and are located on the same horizontal plane as a load (e.g. the CPU), the multiphase power source supplies power to the load. The inventor has realized that in the above solution, the power needs to be transmitted from the output inductor into the load, causing a long intermediate transmission path, high transmission impedance, and substantial power loss, whereby the multiphase power source has low working efficiency.

### SUMMARY

According to the embodiments disclosed by the present application, in a first aspect, the present application provides a power module, including a plurality of power chips, a plurality of input capacitors, a plurality of output inductors, and a first printed circuit board. The plurality of power chips are spaced apart on an upper surface of the first printed circuit board, and input ends of the plurality of power chips are connected to an input power source; the plurality of input capacitors are fixedly arranged at the first printed circuit board; the plurality of input capacitors are connected to the input ends of the plurality of power chips in a one-to-one correspondence manner; the plurality of output inductors are stacked with the plurality of power chips in a vertical direction through the first printed circuit board; input ends of the plurality of output inductors are connected to output ends of the plurality of power chips in a one-to-one correspondence manner; output ends of the plurality of output inductors are connected to a load through a via hole in a third printed circuit board to supply power to the load; the plurality of output inductors are located on a lower surface of the third printed circuit board; the load is located on an upper surface of the third printed circuit board; first areas of the input capacitors, the power chips, and the output inductors are smaller than an area of the upper surface of the first printed circuit board; an area of the first printed circuit board is smaller than an area of the third printed circuit board; and the first areas are surface areas of sides, close to the first printed circuit board, of the input capacitors, the power chips, and the output inductors.

According to the embodiments of the present application, in a second aspect, a server is provided, including a third printed circuit board; a load, arranged on an upper surface of the third printed circuit board; and a plurality of the power modules according to the first aspect or any corresponding implementation, which are spaced apart on a lower surface of the third printed circuit board. The plurality of power modules are connected to the load through a via hole in the third printed circuit board to supply power to the load.

The details of one or more embodiments of the present application are presented in the accompanying drawings and description below. Other features and advantages of the present application will become apparent from the specification, accompanying drawings, and claims.

### BRIEF DESCRIPTION OF THE DRAWINGS

To describe specific implementations of the present application or the technical solutions in the related art more clearly, the following briefly introduces the accompanying drawings for describing the embodiments or the related art. Apparently, the accompanying drawings in the following description show some implementations of the present application, and a person of ordinary skill in the art may still derive other drawings from the accompanying drawings without creative efforts.

FIG. 1 is a schematic diagram of a top view structure of a traditional power supplying architecture;

FIG. 2 is a schematic diagram of a front view structure of a traditional power supplying architecture;

FIG. 3 is a schematic diagram of a front view structure of a power module according to one or more embodiments of the present application;

FIG. 4 is a schematic diagram of a top view structure of a power module according to one or more embodiments of the present application;

FIG. 5 is a schematic diagram of a front view structure of a power module according to another one or more embodiments of the present application;

FIG. 6 is a schematic diagram of a top view structure of a power module according to another one or more embodiments of the present application;

FIG. 7 is a schematic circuit diagram of a power module according to one or more embodiments of the present application;

FIG. 8 is a schematic structural diagram of a soldering point of an output inductor according to one or more embodiments of the present application;

FIG. 9 is a schematic diagram of a front view structure of a power module, with an output inductor being a coupling inductor according to one or more embodiments of the present application;

FIG. 10 is a schematic diagram of a front view structure of a power module, with an input capacitor being embedded according to one or more embodiments of the present application;

FIG. 11 is a schematic structural diagram of a power chip according to one or more embodiments of the present application;

FIG. 12 is a schematic diagram of input voltage conversion according to one or more embodiments of the present application;

FIG. 13 is a schematic diagram of a top view structure of an arrangement mode for an output inductor according to one or more embodiments of the present application;

FIG. 14 is a schematic diagram of a front view structure of an arrangement mode for an output inductor according to another one or more embodiments of the present application;

FIG. 15 is a schematic diagram of a top view structure of an arrangement mode for an output inductor according to another one or more embodiments of the present application;

FIG. 16 is a schematic diagram of a front view structure of a server according to one or more embodiments of the present application;

FIG. 17 is a schematic circuit diagram of a server according to one or more embodiments of the present application;

FIG. 18 is a schematic diagram of a top view structure of solder balls according to one or more embodiments of the present application;

FIG. 19 is a schematic diagram of a front view structure of a power module having solder balls according to one or more embodiments of the present application;

FIG. 20 is a schematic diagram of a front view structure of a connection mode for a power module and a load according to one or more embodiments of the present application;

FIG. 21 is a schematic diagram of a front view structure of a connection mode for a power module and a load according to another one or more embodiments of the present application;

FIG. 22 is a schematic diagram of a front view structure of a heat dissipation device of a server according to one or more embodiments of the present application;

FIG. 23 is a schematic diagram of a front view structure of a heat dissipation device of a server according to another one or more embodiments of the present application;

FIG. 24 is a schematic structural diagram of a server having a controller according to one or more embodiments of the present application; and

FIG. 25 is a schematic diagram of a hardware structure of a server according to one or more embodiments of the present application.

Numerals in the accompanying drawings: 10: multiphase power source; 100: power module; 110: power chip; 111: first pulse width modulation signal port; 112: first current signal port; 113: first temperature signal port; 120: input capacitor; 130: output inductor; 131: magnetic core; 132: coil; 133: soldering point; 140: first printed circuit board; 141: solder ball; 150: second printed circuit board; 160: output capacitor; 170: copper bar; 200: load; 300: printed circuit board; 400: heat dissipation device; 500: third printed circuit board; 510: through hole; 520: blind hole; 530: buried hole; 600: first heat dissipation device; 610: first substrate; 611: screw; 612: nut; 620: first heat dissipation fin; 700: second heat dissipation device; 710: second substrate; 720: second heat dissipation fin; 800: controller; 810: second pulse width modulation signal port; 820: second current signal port; 830: second temperature signal port; 2510: processor; 2520: memory; and 2530: communication interface.

### DETAILED DESCRIPTION

In order to make the objectives, technical solutions, and advantages of the embodiments of the present application clearer, the technical solutions in the embodiments of the present application are clearly and completely described below with reference to the accompanying drawings in the embodiments of the present application. Apparently, the described embodiments are merely some rather than all of the embodiments of the present application. All other embodiments obtained by a person of ordinary skill in the art based on the embodiments of the present application without making creative efforts shall fall within the protection scope of the present application.

A server is a high-performance computer that provides various services on a network. The server provides computing or application services to other clients in the network (such as a computer, a smartphone, an automatic teller machine (ATM), and even large devices such as a train system). As a node of the network, the server stores and processes 80% of data and information on the network, and is also referred to as the soul of the network.

The function of the server is similar to that of an ordinary computer. However, compared with the ordinary computer, the server has higher requirements in terms of stability, security, data throughput, expansibility, and performance. Therefore, hardware such as a central processing unit, a chipset, an internal memory, a disk system, and a network are different from those of the ordinary computer.

The server is also a core infrastructure for building cloud computation or a data center. As the power of the server and the power of an entire cabinet continue to increase, compared with a traditional 12V power supplying architecture, a 48V power supplying architecture gradually receives attention due to its high conversion efficiency and low loss. When a 48V power supplying architecture is used under the same load power, voltage is increased by four times; current is one-quarter of original current; and the transmission loss is significantly reduced. Using the 48V power supplying architecture is an effective measure to optimize energy consumption of a server system.

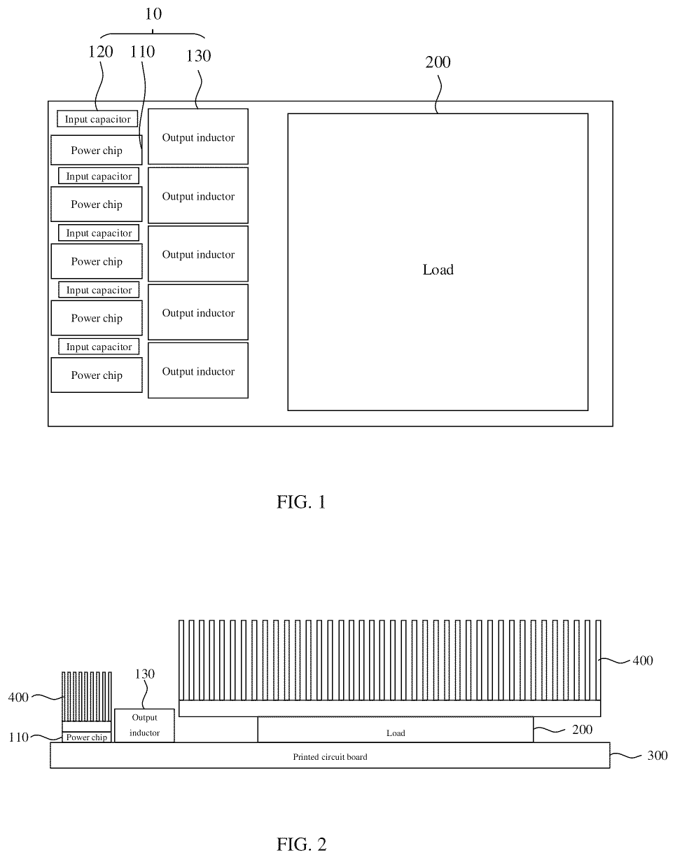

A CPU, as the “brain” of the server, is a primary indicator for measuring performance of the server. CPU power continues to increase, and the problem of increased current loss in a power supplying path of the server receives increasing attention. A traditional CPU power supplying architecture of the server is a horizontal power supplying architecture. A multiphase power source uses a separation solution to supply power to a load. That is, an input capacitor, a power chip, and an output inductor that are included in a voltage regulator (VR) are separated. In some embodiments, as shown in FIG. 1 and FIG. 2, a plurality of power chips 110, a plurality of input capacitors 120, and a plurality of output inductors 130 in a multiphase power source 10 are separately arranged on the same horizontal plane of the printed circuit board 300 as a load 200, to supply power to the load 200. In addition, it should be noted that due to high power of the load, in order to ensure normal operation of the load, the plurality of power chips 110 and the load 200 might further be provided with heat dissipation devices 400 to dissipate heat of the plurality of power chips 110 and the load 200.

In the above solution, there is a large distance in a horizontal space between the multiphase power source 10 and the load 200. The power chips 110 need to transmit power from the output inductors 130 to the load 200, causing a long intermediate power supplying transmission path, high transmission impedance, and substantial power loss, whereby the multiphase power source 10 has low working efficiency, which affects performance of the server.

In view of this, the present application provides a power module, which might shorten a power supplying transmission path and increase a power density of a server.

The following will describe a power module provided in the present application in detail with reference to the accompanying drawings.

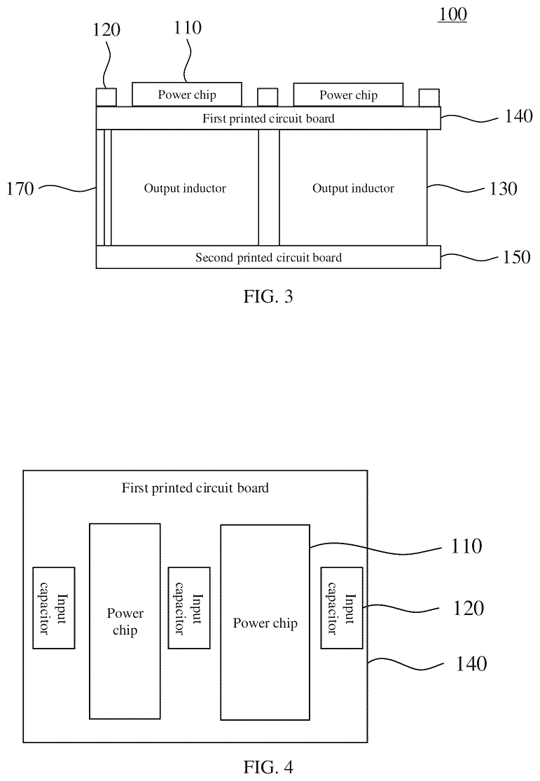

As shown in FIG. 3 to FIG. 7, the power module 100 includes the plurality of power chips 110, the plurality of input capacitors 120, the plurality of output inductors 130, and a first printed circuit board 140.

The plurality of power chips 110 are spaced apart on an upper surface of the first printed circuit board 140. The plurality of input capacitors 120 are fixedly arranged on the first printed circuit board 140. The plurality of input capacitors 120 might be placed in gaps between the plurality of power chips 110. The plurality of output inductors 130 are stacked with the plurality of power chips 110 through the first printed circuit board 140 in a vertical direction.

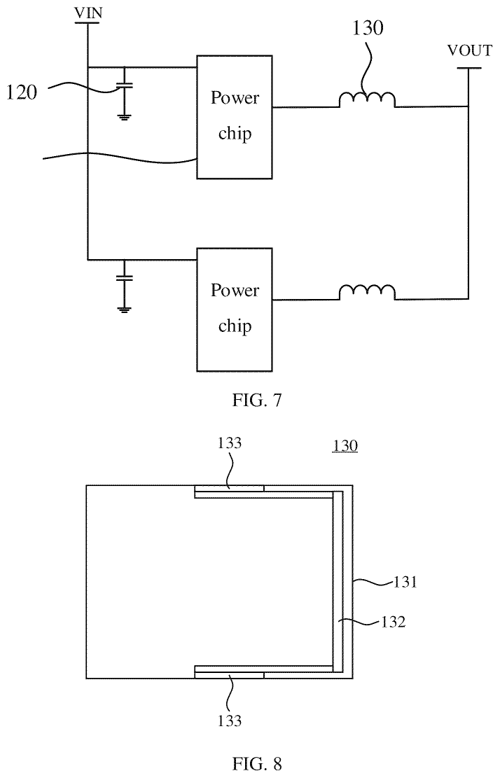

In some embodiments, the plurality of power chips 110 are power supplying chips of the power module 100, in which metal oxide semiconductor field effect transistors (MOSFETs) and driving units are integrated. As shown in FIG. 7, input ends of the plurality of power chips 110 are all connected to an input power source (voltage) VIN. The input ends of the plurality of power chips 110 are connected to the plurality of input capacitors 120 in a one-to-one correspondence manner. That is, one end of each input capacitor 120 is connected to the input end of the corresponding power chip 110, and the other end of the input capacitor 120 is grounded. The input capacitor 120 is configured to filter out a high-frequency interference signal of the power chip 110 connected to the input capacitor 120, thereby preventing the power chip 110 from being broken down by high voltage. Output ends of the plurality of power chips 110 are connected to input ends of the plurality of output inductors 130 in a one-to-one correspondence manner, to achieve an output power source (voltage) VOUT. The output voltage VOUT is configured to supply power to a load. That is, the output ends of the plurality of power chips 110 are connected in series with the corresponding output inductors 130 to form the output voltage VOUT that supplies power to the load. That is, separated VR devices such as the plurality of power chips 110 and the plurality of output inductors 130 are stacked in the vertical direction through the first printed circuit board 140, to integrate a power module 100.

Further, as shown in FIG. 16, output ends of the plurality of output inductors 130 are connected to a load 200 through a via hole in a third printed circuit board 500 to supply power to the load 200. The plurality of output inductors 130 are located on a lower surface of the third printed circuit board 500. The load 200 is located on an upper surface of the third printed circuit board 500. First areas of the input capacitors 120, the power chips 110, and the output inductors 130 are smaller than an area of the upper surface of the first printed circuit board 140. An area of the first printed circuit board 140 is smaller than an area of the third printed circuit board 500. The first areas are surface areas of sides, close to the first printed circuit board 140, of the input capacitors 120, the power chips 110, and the output inductors 130. That is, areas of lower surfaces of the power chips 110, areas of lower surfaces of the input capacitors 120, and areas of upper surfaces of the output inductors 130 are smaller than the area of the upper surface of the first printed circuit board 140.

It should be noted that for ease of understanding, this article provides a specific explanation of a connection mode for the power module 100 and the load 200 in the relevant embodiments where the server is located. It is not explained here.

For example, the plurality of power chips 110 may be arranged on the upper surface of the first printed circuit board 140 in an equal spacing manner, or may be arranged on the upper surface of the first printed circuit board 140 in a non-equal spacing manner.

For example, the load may be a CPU, a graphics processing unit (GPU), a data processing unit (DPU), or the like.

It should be understood that the input capacitors 120 may be filtering capacitors. In some embodiments, the filtering capacitors are energy storage devices mounted at two ends of a rectifier circuit to reduce an alternating current pulse ripple coefficient and improve an efficient and smooth direct current output. Since a filtering circuit requires an energy storage capacitor to have high electric capacity, the most commonly used capacitor is an electrolytic capacitor ranging from hundreds to thousands of microfarads. A positive terminal of the electrolytic capacitor is connected to a positive end of a rectifier output circuit, and a negative terminal of the electrolytic capacitor is connected to a negative end of the circuit. Setting a filtering capacitor may make working performance of an electronic circuit more stable and also reduce interference of alternating pulse ripples on the electronic circuit.

In order to achieve a good filtering effect, a capacitor needs to be discharged slowly. Faster discharging of the capacitor reflects smoother output voltage and a better filtering effect. A discharging speed of the capacitor is related to a capacity C and a load R of the capacitor. A larger C and a larger R reflect slower discharging of the capacitor. In addition, in order to be suitable for use at different frequencies, electrolytic capacitors are also divided into a high-frequency capacitor and a low-frequency capacitor. A high frequency is relatively speaking. A low-frequency filtering capacitor is mainly configured to filter mains supply or filter a rectified transformer, a working frequency of which is 50 Hertz (Hz). A high-frequency filtering capacitor is mainly configured for filtering after a switching power source is rectified, a working frequency of which is several thousand Hz to tens of thousands of Hz. A voltage frequency of sawtooth waves may reach tens of thousands of hertz, even tens of megahertz. The standard for measuring quality of a high-frequency aluminum electrolytic capacitor is a “impedance-frequency” characteristic, which requires low equivalent impedance within a working frequency of a switching power source and has a good filtering effect on high-frequency peak signals generated during working of a semiconductor device.

A printed circuit board (PCB) is referred to as a “printed” circuit board because it is made by using an electronic printing technology. The printed circuit board is a substrate for assembling an electronic component. It is made by using an insulating board as a base material and cutting the insulating board according to a size, and has at least one conductive pattern. Holes (such as element holes, fastening holes, and plated through holes) are distributed on the PCB to replace a chassis of the electronic component in the previous device. A main function of the printed circuit board is to connect various electronic components into a predetermined circuit, to play a role in relay transmission. It is a key electronic interconnect component of an electronic product and is referred to as the “mother of electronic product”. The printed circuit board is used as a substrate and a key interconnect component for electronic component loading and needs to be provided on any electronic device or product.

It should be noted that in this embodiment, there is no limitation on a quantity of the power chips 110, a quantity of the input capacitors 120, and a quantity of the output inductors 130, for example, 3, 5, 8, or 10. The quantity of the power chips 110 and the quantity of the output inductors 130 are the same, and the quantity of the power chips 110 and the quantity of the input capacitors 120 may be the same or different. For example, the quantity of the input capacitors 120 is greater than the quantity of the power chips 110.

In this embodiment, the plurality of output inductors 130 are stacked with the plurality of power chips 110 through the first printed circuit board 140 in the vertical direction. The power module 100 may be directly arranged on the load 200 through the third printed circuit board to supply power to the load 200 in the vertical direction, thereby shortening an intermediate transmission path between the power module 100 and the load 200, reducing transmission impedance, reducing a copper loss of a circuit board path, and improving a power density of the power module 100. It is conductive to reducing server system power consumption, improving an energy efficiency ratio, and helping users save electricity costs. In addition, compared with a traditional power source, the present application might further significantly reduce an area of a circuit board that needs to be occupied by the power module 100, recycle a space around the CPU, minimize power delivery network (PDN) loss, and reduce transmission loss. Furthermore, it is conductive to reducing sizes of a circuit board and the server, reducing processing costs of the circuit board and occupation costs of a data center. Meanwhile, a larger circuit board area might be released for high-speed input/output (I/O) interfaces and memories; maximization of system resource utilization might be promoted; and an optimization space might be provided for signal wiring. This is conductive to improving signal quality and anti-interference capability, and enhancing system operation reliability.

In some embodiments, the output inductors 130 may be arranged on the first printed circuit board 140 or may be arranged inside the first printed circuit board 140. The present application does not limit it. The following will make a detailed explanation to a specific arrangement mode for the output inductors 130 with reference to the accompanying drawings.

In some embodiments, as shown in FIG. 3 and FIG. 4, the power module 100 further includes a second printed circuit board 150. The second printed circuit board 150 is connected to the first printed circuit board 140 through a copper bar 170 for signal transmission. One end of the output inductor 130 that is close to the corresponding power chip 110 is connected to a lower surface of the first printed circuit board 140 in the vertical direction, and one end of the output inductor 130 that is away from the corresponding power chip 110 is connected to an upper surface of the second printed circuit board 150. That is, the output inductor 130 is arranged between the first printed circuit board 140 and the second printed circuit board 150. The first printed circuit board 140, the output inductor 130, and the second printed circuit board 150 are stacked together, and the two ends of the output inductor 130 in the vertical direction are respectively connected to the lower surface of the first printed circuit board 140 and the upper surface of the second printed circuit board 150.

It should be noted that this embodiment does not impose a limitation on the quantity of the output inductors 130. In FIG. 3 and FIG. 4, an example in which the power module includes two output inductors 130 is used.

In this embodiment, the power chip 110, the first printed circuit board 140, the output inductor 130 corresponding to the power chip 110, and the second printed circuit board 150 are stacked in sequence in the vertical direction to integrate the power module 100, which might ensure structural stability of the power module 100.

Further, as shown in FIG. 8, soldering points 133 of the output inductor 130 are arranged at two ends of the output inductor 130 in the vertical direction. The output inductor 130 is connected to the first printed circuit board 140 and the second printed circuit board 150 through the soldering points. That is, one soldering point of the output inductor 130 is connected to the lower surface of the first printed circuit board 140, and the other soldering point of the output inductor 130 is connected to the upper surface of the second printed circuit board 150.

In this embodiment, the soldering points of the output inductor 130 are arranged at the two ends of the output inductor 130 in the vertical direction. This might directly interconnect the output inductor 130 to the first printed circuit board 140 and the second printed circuit board 150, thereby achieving a shortest current path and effectively improving conversion efficiency of the power module 100.

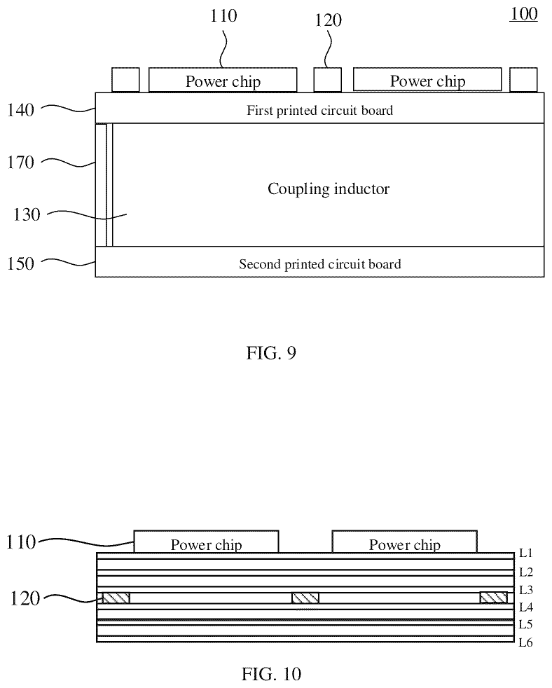

For example, as shown in FIG. 9, in order to further reduce a volume and height of the power module 100, the output inductor 130 may be configured as a coupling inductor. Two coils inside the coupling inductor may be coupled in a codirectional coupling manner to enhance an intensity of a magnetic field and further achieve an effect of further reducing inductance.

It should be understood that an inductance element is also referred to as a self-inductance element. If a magnetic flux generated by each of two or more coils is interlinked with a magnetic flux generated by the other coil, these coils are considered to have magnetic coupling or mutual induction. If it is assumed that these coils are stationary and resistances in the coils and distributed capacitance between turns of the coils are ignored, the coils having the magnetic coupling may be represented as idealized coupled inductors.

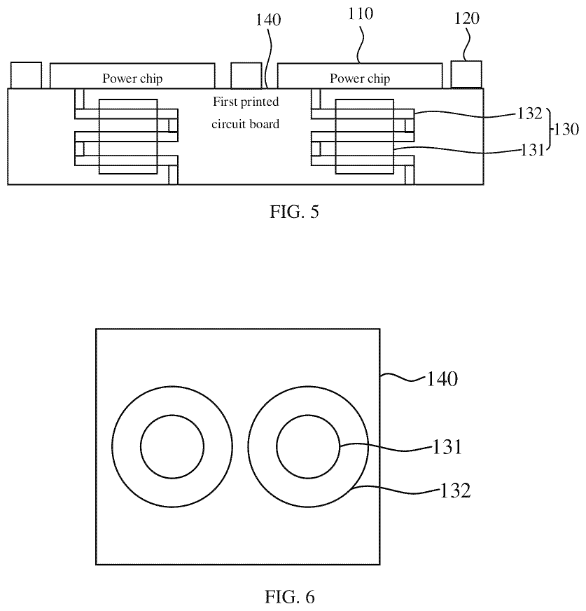

In another optional implementation, as shown in FIG. 5 and FIG. 6, the first printed circuit board 140 is of a multilayer structure. Each output inductor 130 includes a magnetic core 131 and a coil 132. The magnetic core 131 is buried inside the first printed circuit board 140, and the coil 132 is composed of copper surface winding of each layer in the first printed circuit board 140. In some embodiments, a copper surface of each layer inside the first printed circuit board 140 is designed into a style of an inductance coil, and all layers are connected by using blind holes and buried holes to form the coil 132.

It should be understood that a layer of the printed circuit board is a copper layer. The printed circuit board may be formed by pressing the copper layers and a base material. The present application does not impose a limitation on a quantity of the layers of the first printed circuit board 140. For example, the first printed circuit board 140 is a four-layer printed circuit board or a six-layer printed circuit board.

In some embodiments, according to classification of circuit layers of the printed circuit board, the printed circuit board may be divided into a single-sided board, a double-sided board, and a multilayer board. A common multilayer board is generally a four-layer or six-layer board, and a complex multilayer board may include dozens of layers. The single-sided board is the most basic printed circuit board, with components concentrated on one side and wires concentrated on the other side. A printed circuit board with wires only provided on one side is referred to as a single-sided board. On the double-sided board, wires are distributed on both sides, but to use the wires on the two sides, there needs to be a proper circuit between the two sides for connection. This “bridge” between circuits is referred to as a via. A via is a small hole filled or coated with metal on a printed circuit board, which might be connected to the wires on the two sides. Since an area of the double-sided board is twice as large as an area of the single-sided board, the double-sided board solves a difficulty of staggered wiring in the single-sided board (which might be connected to the other side through vias), and is more suitable for being applied to a more complex circuit than the single-sided board. The multilayer board has a larger wiring area and may be a combination of a single-sided board and a double-sided board. For example, a printed circuit board that uses a double-sided board as an inner layer and two single-sided boards as outer layers, which are alternately arranged together through a positioning system and an insulating adhesive material and interconnected according to conductive pattern design requirements, becomes a four-layer printed circuit board, or referred to as a multilayer printed circuit board. For another example, a printed circuit board that uses two double-sided boards as inner layers and two single-sided boards as outer layers, which are alternately arranged together through a positioning system and an insulating adhesive material and interconnected according to conductive pattern design requirements is a six-layer printed circuit board.

It should be noted that a quantity of layers of a board does not necessarily mean there are some independent wiring layers. In a special case, an empty layer may be added to control a board thickness. Usually, the quantity of the empty layer is even, and the empty layers usually include two outermost layers. Most motherboards have a four to eight-layer structure, but theoretically, a 100-layer printed circuit board may be made.

In addition, this embodiment does not impose a limitation on the quantity of the output inductors 130. For example, there may be 2, 4, or 5 output inductors. In FIG. 5 and FIG. 6, an example in which the power module 100 includes two output inductors 130 is used. The present application makes an explanation on a specific structure of an output inductor.

In this embodiment, by embedding the output inductors 130 into the first printed circuit board 140, a height of the power module 100 might be significantly reduced, which further reduces the volume of the power module 100, thereby improving the power density of the power module 100.

In some embodiments, the input inductors 120 may be arranged on the first printed circuit board 140 or may be arranged inside the first printed circuit board 140. The present application does not limit it. The following will make a detailed explanation on a specific arrangement mode for the input inductors 120 with reference to the accompanying drawings.

In some embodiments, as shown in FIG. 3 to FIG. 5, the input capacitors 120 may be fixedly arranged on the upper surface of the first printed circuit board 140, and the input capacitors 120 are located on at least one sides of the power chips 110. That is, the input capacitor 120 may be arranged on one side of one power chip 110, or may be arranged on two sides of the power chip 110.

It should be noted that this embodiment does not impose a limitation on the quantity of the input inductors 120. In FIG. 3 and FIG. 5, an example in which the power module 100 includes three input inductors 120 is used.

In this embodiment, by directly setting the input capacitors 120 on the upper surface of the first printed circuit board 140, efficiency of manufacturing the power module 100 might be improved.

In another optional implementation, as shown in FIG. 10, the first printed circuit board 140 is of a multilayer structure, and the input capacitors 120 are embedded between a ground layer and an output power layer of the first printed circuit board 140.

In some embodiments, an example in which the first printed circuit board 140 is a six-layer printed circuit board is used to explain an arrangement mode for the input capacitors 120. The input capacitors 120 are embedded between layer L3 and layer L4 to replace an original glass fiber epoxy resin copper-clad plate (FR4) material between the layers. Layer L3 is a ground layer GND, and layer L4 is an output power layer. Positive and negative terminals of the input capacitors 120 are respectively connected to layer L4 and layer L3.

It should be understood that the FR4 material is a glass fiber reinforced epoxy laminate, which looks like a thin woven fabric board. FR represents a flame retardant, and the digit 4 means a code of a level of a fire-resistant material. It represents a material specification in which a resin material needs be able to be self-extinguished after being burned. A glass fiber structure provides structural stability for the material, and a glass fiber layer is covered with flame-retardant epoxy resin, which brings durability and high mechanical properties to the material. Due to its high strength and flame retardancy, the FR4 material might be selected as base materials for most printed circuit boards.

In this embodiment, the input capacitors 120 that are originally placed on a surface of the first printed circuit board 140 are embedded into the first printed circuit board 140, which might reduce an occupied board area and further improve the power density.

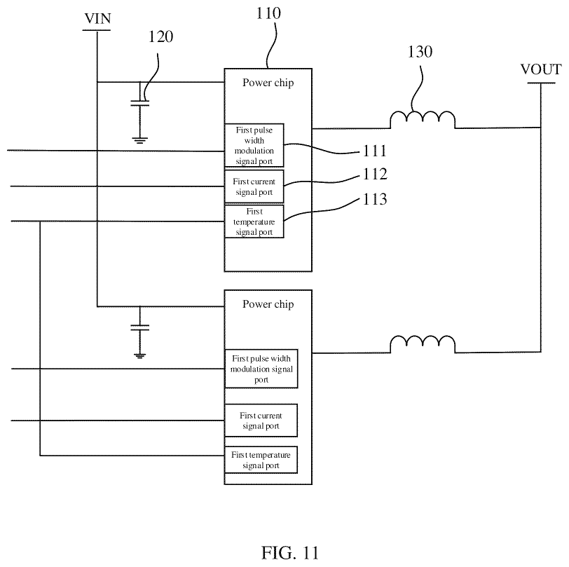

For example, as shown in FIG. 11, the power chip 110 is provided with a first pulse width modulation (PWM) signal port 111. The first pulse width modulation signal port 111 is connected to a front-end controller. The power chip 110 is configured to: receive a pulse width modulation signal from the controller through the first pulse width modulation signal port 111 and adjust output voltage according to the pulse width modulation signal, to achieve normal operation.

In some embodiments, a pulse width modulation technology may be understood as a technology for modulating widths of a series of pulses to equivalently obtain a desired waveform (including a shape and an amplitude). The pulse width modulation technology is most widely used in an inverter circuit, a basic principle of which is to control on or off of an inverter circuit switching device, whereby an output end obtains a series of pulses with equal amplitudes, and these pulses are used to replace a waveform required by a sine wave. That is, a plurality of pulses are generated in half a cycle of an output waveform, and equivalent voltages of the pulses have a sine waveform, whereby an obtained output is smooth and has a few of low-order harmonics. By modulating widths of the pulses according to a rule, output voltage and an output frequency of the inverter circuit might be changed. In addition, in a PWM waveform, the amplitudes of the pulses are equal. To change the amplitudes of the equivalent output sine waves, the widths of the pulses are changed according to the same proportionality coefficient.

Further, as shown in FIG. 11, each power chip 110 is further provided with a first current (IMON) signal port 112 and/or a first temperature (Temp) signal port 113. That is, the power chip 110 may only have the first current signal port 112 or the first temperature signal port 113, or may have both the first current signal port 112 and the first temperature signal port 113. In some embodiments, the first current signal port 112 and the first temperature signal port 113 are also connected to the front-end controller, and the power chip 110 is further configured to send detected current to the controller through the first current signal port 112; and/or, the power chip 110 is further configured to send a detected temperature to the controller through the first temperature signal port 113.

For example, the first temperature signal ports 113 corresponding to the plurality of power chips 110 may be connected together to send a maximum temperature among a plurality of detected temperatures to the controller. For example, the power module 100 includes two power chips 110. A detected temperature obtained by the first temperature signal port 113 of a first power chip is 25 degrees Celsius (° C.), and a detected temperature obtained by the first temperature signal port 113 of a second power chip is 30° C. In this case, the detected temperature obtained by the first temperature signal port 113 of the second power chip is sent to the controller.

In this embodiment, since the detected currents are sent to the controller through the first current signal ports 112, it is convenient for the controller to monitor the currents of the power chips 110 to avoid a current overload from affecting normal operations of the power chips 110. Since the detected temperatures are sent to the controller through the first temperature signal ports 113, it is convenient for the controller to monitor the temperatures of the power chips 110 to avoid an excessive high temperature from affecting normal operations of the power chips 110.

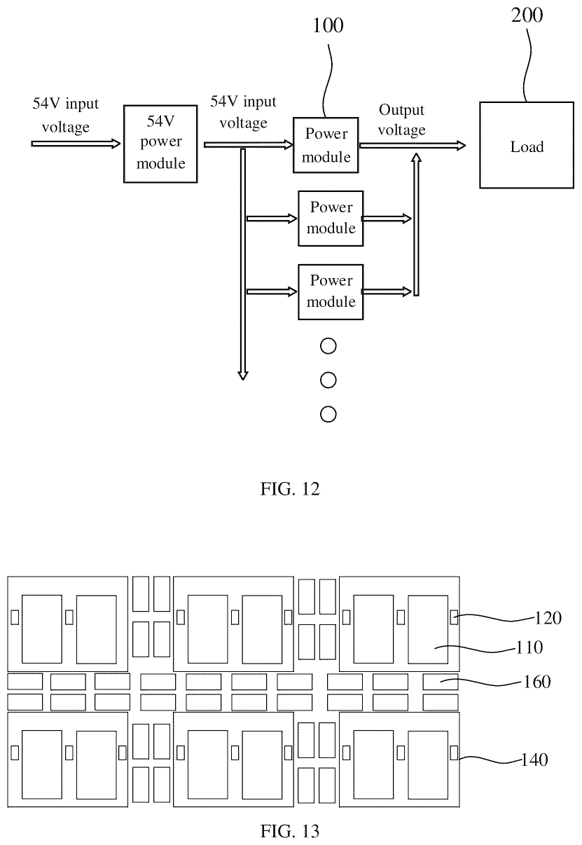

In some optional implementations, in order to further reduce volumes of the output inductors 130 and reduce the height of the power module 100, this embodiment might reduce traditional 12V input voltage to around 5V input voltage, to supply power to the power module 100. In some embodiments, as shown in FIG. 12, system input voltage is 54 V, which is converted into intermediate voltage of about 5 V through a 54V power module, to supply power to the power module, thus finally outputting working voltage that meets a load requirement to the load.

In this embodiment, changing the traditional 12 V input voltage into the 5 V input voltage is conductive for improving conversion efficiency of the power module 100. Meanwhile, reducing the input voltage might decrease an inductance value of an inductor, which is conductive for further reducing the volume of the power module 100.

In some optional implementations, in order to meet a dynamic performance requirement of the load, the power module 100 further includes an output capacitor. The output capacitor is configured to store electrical energy to provide sufficient energy for the load 200 with dynamic performance, thus avoiding excessive voltage fluctuations in an output of the power module 100 from affecting normal operation of the load 200.

The following will make a specific explanation to an arrangement mode for the output capacitor with reference to the accompanying drawings.

As shown in FIG. 13, in some embodiments, the output capacitor 160 may be directly arranged on the upper surface of the third printed circuit board 500 and located in gaps between a plurality of power modules 100.

In this embodiment, arranging the output capacitor 160 directly on the upper surface of the third printed circuit board 500 might improve production efficiency of the power module 100 and reduce production costs of the power module 100.

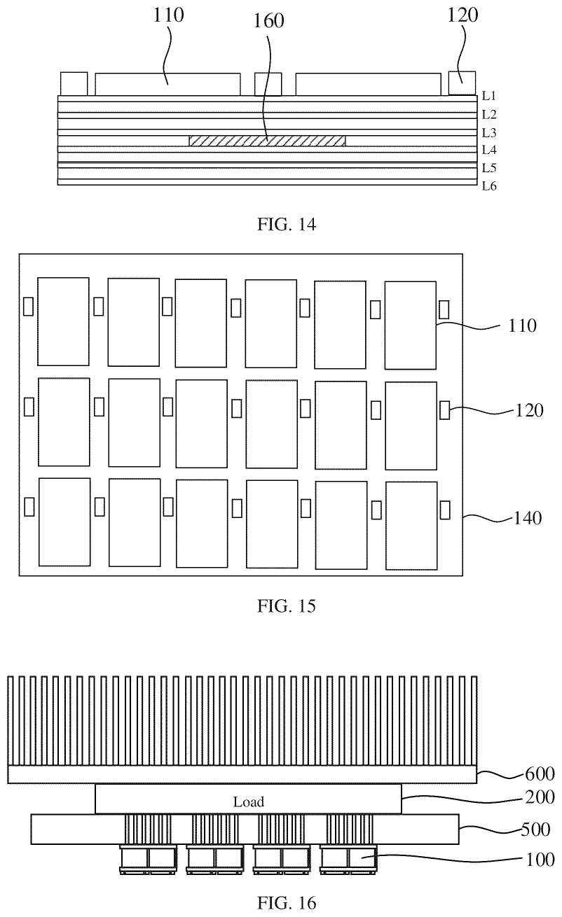

As shown in FIG. 14 and FIG. 15, in another optional implementation, the first printed circuit board 140 of the power module 100 is of a multilayer structure, and the output capacitor 160 is embedded between the ground layer and the output power layer of the first printed circuit board 140.

In some embodiments, an example in which the first printed circuit board 140 is a six-layer printed circuit board is used to explain an arrangement mode for the output capacitor 160. The input capacitor 160 is embedded between layer L3 and layer L4 to replace an original glass fiber epoxy resin copper-clad plate (FR4) material between the layers. Layer L3 is a ground layer GND, and layer L4 is an output power layer. Positive and negative terminals of the output capacitor 160 are respectively connected to layer L4 and layer L3.

In this embodiment, the output capacitor 160 originally placed on a surface of the third printed circuit board 500 is embedded into the first printed circuit board 140, without reserving a capacitor space on the third printed circuit board 500. This might reduce a gap between two adjacent power modules 100 arranged on the third printed circuit board 500, which greatly reduces the occupied board area and improve the power density.

The present application further provides a server, which will be described in detail below with reference to the accompanying drawings.

As shown in FIG. 16, the server provided by the present application includes a plurality of the power modules 100 as described in the above embodiments, a load 200, and a third printed circuit board 500. The plurality of power modules 100 are spaced apart on a lower surface of the third printed circuit board 500, and the load 200 is arranged on an upper surface of the third printed circuit board 500. The plurality of power modules 100 are connected to the load 200 through a via hole in the third printed circuit board 500.

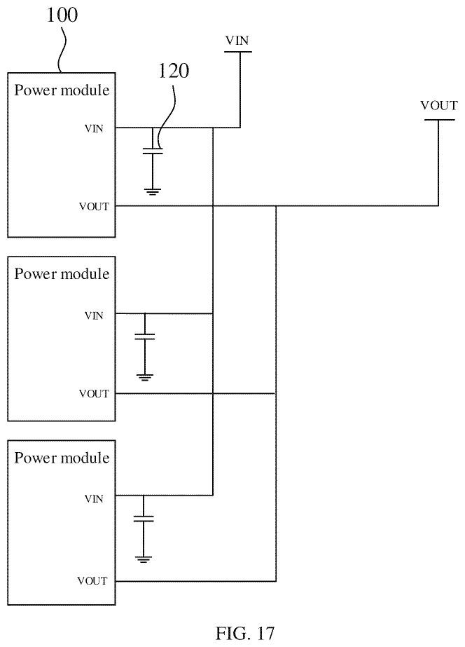

In some embodiments, as shown in FIG. 17, input ends of the plurality of power modules 100 are all connected to input voltage VIN, and output ends of the plurality of power modules 100 are connected in parallel to form output voltage VOUT, to supply power to the load 200.

For example, this embodiment does not impose a limitation a quantity of the power modules included in the server. For example, the server may include two, three, eight, or another number of power modules 100. The plurality of power modules 100 may be uniformly arranged on the upper surface of the third printed circuit board 500 (in a manner of making spacings between two adjacent power modules equal), or non-uniformly arranged on the upper surface of the third printed circuit board 500 (in a manner of making spacings between two adjacent power modules not equal). The present application does not impose a specific limitation.

The present application does not impose a limitation on a quantity of layers of the third printed circuit board, namely, the third printed circuit board may be a single-layer board, a double-layer board, or a multilayer board.

According to the server provided in this embodiment, the power modules 100 are integrated by separated voltage inverters such as the input capacitors 120, the power chips 110, and the output inductors 130, and the plurality of power modules 100 integrated are directly attached to a back surface of the load 200, whereby the power modules 100, the third printed circuit board 500, and the load 200 are stacked in a vertical direction. Compared with a traditional power supplying architecture, this might significantly shorten a power supplying path, reduce transmission impedance, and reduce a copper loss in a printed circuit board path. This is conducive to reducing server system power consumption, improving an energy efficiency ratio, and helping users save electricity costs. Meanwhile, this might significantly reduce a board area occupied by power supplying devices, improve a power density of the server, reduce sizes of a printed circuit board and the server, and reduce processing costs of the printed circuit board and occupation costs of a data center. In addition, a larger printed circuit board area might be released for high-speed input/output (I/O) interfaces and memories; maximization of system resource utilization might be promoted; and an optimization space might be provided for signal wiring. This is conductive to improving signal quality and anti-interference capability, and enhancing system operation reliability.

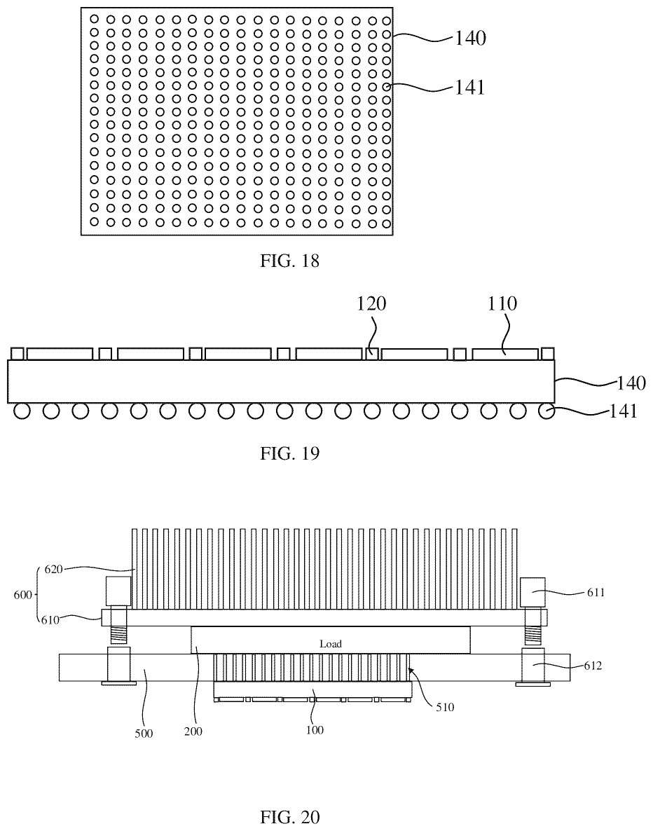

As shown in FIG. 18 and FIG. 19, in some optional implementations, solder balls 141 are arranged on the lower surface of the first printed circuit board 140 of the power module 100 or on the lower surface of the second printed circuit board 150 by using a ball bonding process. The plurality of power modules 100 are connected to the load 200 through the solder balls 141 and the via hole in the third printed circuit board 500. That is, the output ends of the plurality of output inductors 130 are connected to the load 200 through the solder balls and the via hole in the third printed circuit board 500. In this embodiment, through the solder balls 141, the power modules 100 arranged on the two opposite surfaces of the third printed circuit board 500 might be more quickly and more conveniently electrically connected to the load 200.

In some embodiments, the via hole in the third printed circuit board 500 includes at least one of a through hole, a buried hole, and a blind hole.

It should be understood that the blind hole is located in surfaces of a top layer and a bottom layer of the printed circuit board, and has a particular depth to connect a surface-layer line of the printed circuit board to an inner-layer line below. The depth of the hole usually does not exceed a ratio (hole diameter). The buried hole is a connecting hole located on an inner layer of the printed circuit board, which does not extend to a surface of the printed circuit board. Like wiring between inner layers of the printed circuit board, the buried hole cannot be seen from the surface of the printed circuit board. The through hole penetrates through the printed circuit board and might be configured for implementing internal interconnection or serves as a mounting and positioning hole for a component.

The following will explain a specific mode for connecting the plurality of power modules 100 to the load 200 through the solder balls and the third printed circuit board 500 with reference to the accompanying drawings.

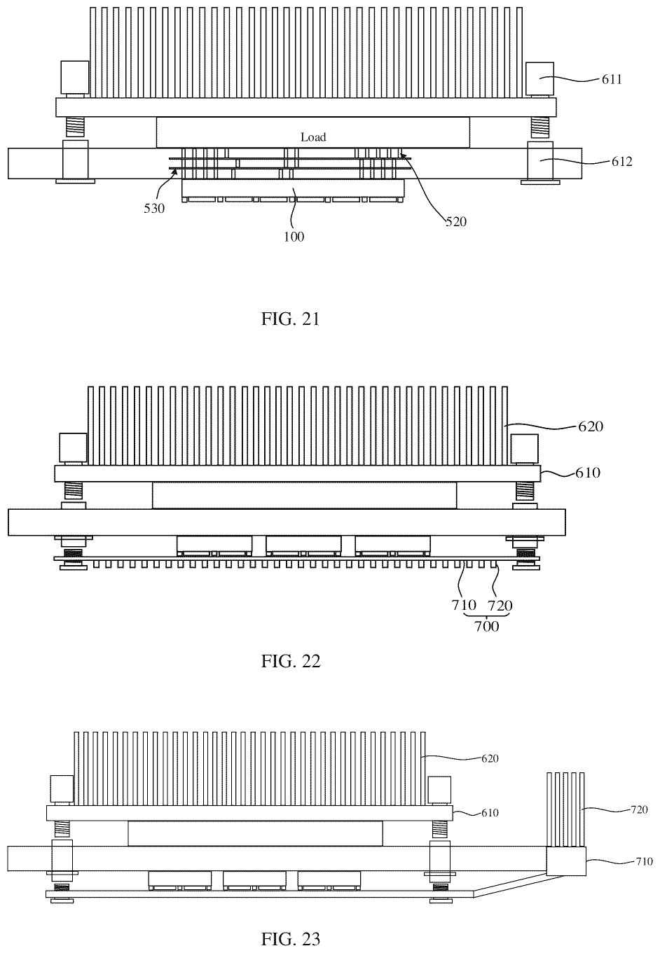

As shown in FIG. 20, in some optional implementations, the third printed circuit board 500 is provided with through holes 510. The plurality of power modules 100 are connected to the load 200 by bonding the solder balls 141 with the through holes 510.

In this embodiment, different power modules 100 might be customized for different loads 200. In this case, a definition of back pins of the power modules 100 is exactly the same as a definition of the through holes made when the load 200 is attached to the third printed circuit board 500. The solder balls 141 on the back surfaces of the power modules 100 might be completely attached to the through holes in the third printed circuit board 500, which further improves reliability of connection between the load 200 and the power modules 100.

As shown in FIG. 21, in some other optional implementations, the third printed circuit board 500 is provided with blind holes 520 and buried holes 530 The plurality of power modules 100 are connected to the load 200 through the blind holes 520 and the buried holes 530.

In this embodiment, the load 200 and the power modules 100 are connected through the blind holes 520 and the buried holes 530, which might ignore a via hole difference between different loads 200, whereby different loads 200 might share the same power module 100, which improves universality of the power module 100.

As shown in FIG. 20 and FIG. 21, due to high power of the load 200, in order to avoid the impact on the normal operation of the load 200, in some optional implementations, a first heat dissipation device 600 is arranged on the load 200. The first heat dissipation device 600 is configured to dissipate heat of the load 200. In some embodiments, the first heat dissipation device 600 may be fixed to the third printed circuit board 500 through screws 611 and nuts 612.

Since the power modules 100 and the load 200 are arranged in the vertical direction, there are basically no heat dissipation controller or airflow for heat dissipation. However, the power module 100 is a power device that may generate a large amount of heat due to current flowing. Without a heat dissipation environment, the power module 100 may have a high working temperature, which affects conversion efficiency of the power module 100 and even leads to overheating and power failure of the power module 100. The following will make a detailed explanation to the heat dissipation device of the power module 100 in the present application with reference to the accompanying drawings.

As shown in FIG. 22, the server includes a first heat dissipation device 600 and a second heat dissipation device 700. In some embodiments, the first heat dissipation device 600 includes a first substrate 610. The first substrate 610 is arranged on one side of the load 200 away from the third printed circuit board 500. The second heat dissipation device 700 includes a second substrate 710. The second substrate 710 is arranged on one side of the power module 100 away from the third printed circuit board 500. The first substrate 610 and the second substrate 710 are connected through the screws 611 and the nuts 612.

In some embodiments, the nuts 612 have screw holes in two ends in the vertical direction. Each screw 611 on the first substrate 610 is mounted to one screw hole of each nut 612, and each screw 611 on the second substrate 710 is mounted to the other screw hole of the nut 612. The heat of the power module 100 is transferred to the first heat dissipation device 600 of the load 200 through heat transfer of the screws 611 and the nuts 612. The screws 611 and nuts 612 play a role of positioning the two heat dissipation devices and reducing the impact caused by adding of positioning screw holes on the layout and wiring of the third printed circuit board 500, and also play a role in heat transfer.

In this embodiment, the first substrate 610 and the second substrate 710 are connected through the screws 611 and the nuts 612. The heat of the power module 100 might be transferred to the first heat dissipation device 600 of the load 200 for heat dissipation through the heat transfer of the screws 611 and the nuts 612, thereby performing heat dissipation on the power module 100 in a limited space and avoiding the impact, caused by an excessively high temperature of the power module 100, on the normal operation of the power module 100.

For example, for enhancement of heat dissipation, the screws 611 and the nuts 612 may be made of a material with high thermal conductivity. For example, the screws 611 and the nuts 612 may be made of metal copper or metal aluminum.

Further, as shown in FIG. 22 and FIG. 23, in some optional implementations, in order to improve the heat dissipation capability of the heat dissipation device, the first heat dissipation device 600 further includes first heat dissipation fins 620 extending from the first substrate 610 in the vertical direction, and the second heat dissipation device 700 further includes second heat dissipation fins 720 connected to the second substrate 710.

It should be understood that the fins are basic heat transfer elements, which are used to enlarge a heat exchange area and improve heat transfer efficiency. The fins may be regarded as extensions and expansions of partition plates. Different forms of the fins might for strong turbulence in a flowing channel of air, to break or recombine a flowing boundary layer and a thermal boundary layer, thereby enhancing heat transfer. The fins might also improve the overall strength of the heat dissipation device, to effectively enlarge its application range.

The present application does not impose a limitation on the arrangement mode for the heat dissipation fins. The following will provide a specific explanation to a heat dissipation mode of the heat dissipation fins in conjunction with the accompanying drawings.

In some embodiments, as shown in FIG. 22, the first heat dissipation fins 620 extend outwards from the first substrate 610, and the second heat dissipation fins 720 extend outwards from the second substrate 710. That is, in the vertical direction, the first heat dissipation fins 620 may extend upwards from the first substrate 610, and the second heat dissipation fins 720 may extend downwards from the second substrate 710.

It should be noted that in this embodiment, the second heat dissipation device 700 needs to meet a requirement for a lower limit height of the third printed circuit board 500. That is, a sum of a height of the power module 100 in the vertical direction, a height of the second substrate 710 in the vertical direction, and a height of the second heat dissipation fins 720 in the vertical direction needs to be less than the lower limit height of the third printed circuit board 500. The lower limit height is a preset value, which might be a height specified by a designer.

In another optional implementation, as shown in FIG. 23, the second substrate 710 may extend to one side of the third printed circuit board 500, whereby an extension direction of the second heat dissipation fins 720 is the same as an extension direction of the first heat dissipation fins 620. For example, in the vertical direction, the second substrate 710 may extend to a left or right side of the third printed circuit board 500, whereby the second heat dissipation fins 720 and the first heat dissipation fins 620 may extend in the same direction. For example, the second heat dissipation fins 720 may extend upwards from the second substrate 710.

In this embodiment, the second substrate 710 extends to one side of the third printed circuit board 500, and then the extension direction of the second heat dissipation fins 720 is made to be the same as the extension direction of the first heat dissipation fin 620, which might enable the second heat dissipation fins 720 to receive airflow from a lateral direction and improve heat dissipation efficiency.

In addition, this embodiment does not impose any limitation on shapes of the heat dissipation fins. For example, the first heat dissipation fins 620 and the second heat dissipation fins 720 may be flat fins, louver fins, serrated fins, porous fins, corrugated fins, or fins in other shapes. The shape of the first heat dissipation fin 620 and the shape of the second heat dissipation fin 720 may be the same or different. For example, both the first heat dissipation fin 620 and the second heat dissipation fin 720 may be straight fins, or one of the first heat dissipation fin 620 and the second heat dissipation fin 720 is a flat fin, and the other one of the first heat dissipation fin 620 and the second heat dissipation fin 720 is a serrated fin.

In this embodiment, there is no limitation on the quantity of the power modules included in the server, such as 2, 3, or 5. In the accompanying drawings, an example in which the server includes six power modules is used.

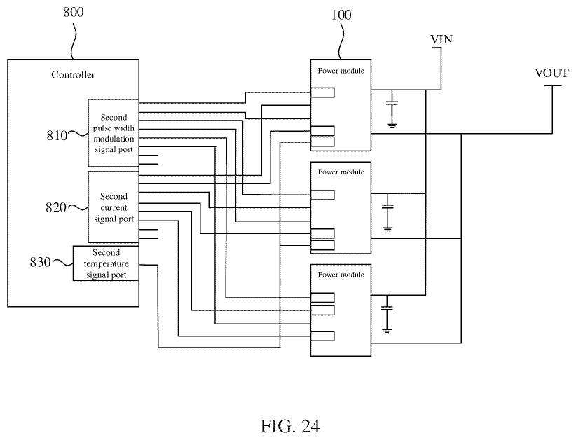

In some optional implementations, as shown in FIG. 24, the server further includes a controller 800. The controller 800 is provided with a second pulse width modulation signal port 810. The controller 800 sends a pulse width modulation signal to the power modules 100 through the second pulse width modulation signal port 810, and the pulse width modulation signal is configured to adjust output voltages of the power modules 100.

In some embodiments, the controller 800 is connected to the first pulse width modulation signal ports 111 of the power modules 100 through the second pulse width modulation signal port 810, and transmits the pulse width modulation signal to control the output voltages of the power modules 100.

Further, the controller 800 further includes a second current signal port 820 and/or a second temperature signal port 830. The controller 800 is further configured to obtain detected currents from the power modules 100 through the second current signal port 820; and/or, the controller 800 is further configured to obtain a detected temperature from the power modules 100 through the second temperature signal port 830.

In this embodiment, since the detected currents are sent to the controller 800 through the second current signal port 820, it might be convenient for the controller 800 to monitor the currents of the power modules 100 to avoid a current overload from affecting normal operations of the power modules 100. Since the detected temperatures are sent to the controller through the second temperature signal port 830, it might be convenient for the controller 800 to monitor the temperatures of the power modules 100 to avoid an excessively high temperature from affecting normal operations of the power modules 100.

For example, the first temperature signal ports corresponding to the plurality of power modules 100 might be connected to the controller 800 after being connected together, and the controller 800 obtains a maximum temperature among a plurality of detected temperatures.

An embodiment of the present application further provides a server which has the power module shown in the above embodiments.

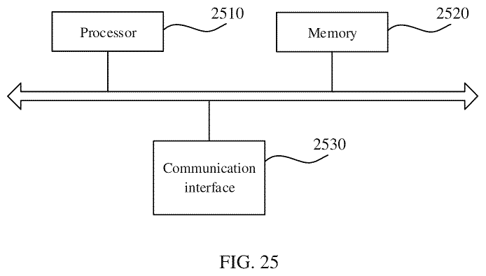

Referring to FIG. 25, FIG. 25 is a schematic structural diagram of a server according to an embodiment of the present application. As shown in FIG. 25, the server includes: one or more processors 2510, a memory 2520, and interfaces configured to connect the components and including a high-speed interface and a low-speed interface. The various components are in communicative connection to each other using different buses, and might be mounted on a common motherboard or in other ways as needed. The processor might process instructions executed in the server, including instructions stored in or on the memory to display graphical information of a graphical user interface (GUI) on an external input/output apparatus (such as a display device coupled to an interface). In some optional implementations, if necessary, a plurality of processors and/or a plurality of buses might be used together with a plurality of memories and a plurality of memories. Similarly, a plurality of servers might be connected. The devices provide some necessary operations (such as serving as a server array, a group of blade servers, or a multiprocessor system). In FIG. 25, one processor 2510 is taken as an example.

The processor 2510 may be a central processing unit, a network processor, or a combination thereof. The processor 2510 may further include a hardware chip. The above hardware chip may be an application-specific integrated circuit, a programmable logic device, or a combination thereof. The above-mentioned programmable logic device might be a complex programmable logic device, a field programmable logic gate array, a general-purpose array logic, or any combination thereof.

The memory 2520 may include a program storage region and a data storage region. The program storage region may store an operating system and an application program required by at least one function. The data storage region may store data created according to use of the server. In addition, the memory 2520 may include a high-speed random access memory and may further include a non-transient memory, such as at least one disk storage device, a flash memory device, or other non-transient solid-state storage devices. In some optional implementations, the memory 2520 includes a memory remotely located with respect to the processor 2510. These remote memories might be connected to the server through a network. Examples of the above network include, but are not limited to, Internets, intranets, local area networks, mobile communication networks, and combinations thereof.

The memory 2520 may include a volatile memory, such as a random access memory. Or, the memory may include a non-transitory memory, such as a flash memory, a hard disk drive, or a solid-state disk drive. The memory 20 might further include a combination of the aforementioned types of memories.

The server further includes a communication interface 2530, used for communicating the server with other devices or communication networks.

In the description of this specification, the description referring to the terms “this embodiment”, “one embodiment”, “some embodiments”, “an example”, “specific examples”, “some examples”, or the like means that specific features, structures, materials or characteristics described in connection with the embodiments or examples are included in at least one embodiment or example of the present application. In this specification, the schematic representations of the above terms are not necessarily intended to refer to the same embodiment or example. Furthermore, the specific features, structures, materials or characteristics described may be combined in any suitable manner in any one or more embodiments or examples. In addition, those skilled in the art may combine the different embodiments or examples described in this specification, as well as the features of different embodiments or examples, without mutual contradictions.

In addition, the terms “first” and “second” are used for descriptive purposes only and are not to be construed as indicating or implying relative importance or to implicitly indicate the number of technical features indicated. From this, features defined as “first” and “second” may explicitly or implicitly include at least one feature. In the description of the present application, “plurality” means at least two, such as two and three unless it is in some embodiments defined otherwise.

In the descriptions of the present application, it should be understood that orientations or positional relationships indicated by “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, “anticlockwise”, “axial”, “radial”, “circumferential” and the like are orientations or positional relationships as shown in the drawings, and are only for the purpose of facilitating and simplifying the descriptions of the present application instead of indicating or implying that devices or elements indicated must have particular orientations, and be constructed and operated in the particular orientations, whereby these terms are not construed as limiting the present application.

In the present application, unless otherwise expressly specified and limited, the terms “mount”, “connect”, “connection”, “fix”, and the like should be understood in a broad sense, such as, a fixed connection, a detachable connection, an integrated connection, a mechanical connection, an electrical connection, a direct connection, an indirect connection through an intermediate medium, an internal communication of two elements, or interaction between two elements, unless expressly specified otherwise. Those of ordinary skill in the art might understand the specific meanings of the above terms in this application according to specific situations.

The foregoing descriptions are merely some embodiments of the present application, but are not intended to limit present application. Any modification, equivalent replacement, and simple improvement that are made within the essential content of present application shall fall within the protection scope of the present application.

1. A power module, comprising a plurality of power chips, a plurality of input capacitors, a plurality of output inductors, and a first printed circuit board, wherein
the plurality of power chips are spaced apart on an upper surface of the first printed circuit board, and input ends of the plurality of power chips are connected to an input power source;
the plurality of input capacitors are fixedly arranged at the first printed circuit board; the plurality of input capacitors are connected to the input ends of the plurality of power chips in a one-to-one correspondence manner; and
the plurality of output inductors are stacked with the plurality of power chips in a vertical direction through the first printed circuit board; input ends of the plurality of output inductors are connected to output ends of the plurality of power chips in a one-to-one correspondence manner; output ends of the plurality of output inductors are connected to a load through a via hole in a third printed circuit board to supply power to the load; the plurality of output inductors are located on a lower surface of the third printed circuit board; the load is located on an upper surface of the third printed circuit board; first areas of the plurality of input capacitors, the plurality of power chips, and the plurality of output inductors are smaller than an area of the upper surface of the first printed circuit board; an area of the first printed circuit board is smaller than an area of the third printed circuit board; and the first areas are surface areas of sides, close to the first printed circuit board, of the plurality of input capacitors, the plurality of power chips, and the plurality of output inductors.

2. The power module according to claim 1, wherein the power module further comprises a second printed circuit board; the second printed circuit board is connected to the first printed circuit board through a copper bar; and
ends of the plurality of output inductors close to corresponding power chips of the plurality of power chips in the vertical direction are connected to a lower surface of the first printed circuit board, and ends of the plurality of output inductors away from the corresponding power chips in the vertical direction are connected to an upper surface of the second printed circuit board.

3. The power module according to claim 2, wherein soldering points of the plurality of output inductors are arranged at two ends of the plurality of output inductors in the vertical direction, and the plurality of output inductors are connected to the first printed circuit board and the second printed circuit board through the soldering points.

4. The power module according to claim 2, wherein a solder ball is arranged on a lower surface of the second printed circuit board, and the second printed circuit board is arranged on the lower surface of the third printed circuit board through the solder ball; and the output ends of the plurality of output inductors are connected to the load through the solder ball and the via hole in the third printed circuit board.

5. The power module according to claim 1, wherein the first printed circuit board is of a multilayer structure, and the plurality of output inductors comprise magnetic cores and coils;
the magnetic cores are buried inside the first printed circuit board; and
the coils are composed of copper surface windings in layers of the first printed circuit board.

6. The power module according to claim 5, wherein a solder ball is arranged on a lower surface of the first printed circuit board, and the first printed circuit board is arranged on the lower surface of the third printed circuit board through the solder ball; and the output ends of the plurality of output inductors are connected to the load through the solder ball and the via hole in the third printed circuit board.

7. The power module according to claim 4, wherein the via hole comprises at least one of a through hole, a buried hole, or a blind hole.

8. The power module according to claim 1, wherein the first printed circuit board is of a multilayer structure; the plurality of input capacitors are embedded between a ground layer and an output power layer of the first printed circuit board.

9. The power module according to claim 1, wherein the power module further comprises a plurality of output capacitors; and the plurality of output capacitors are configured to supplement energy for dynamic performance of the load.

10. The power module according to claim 9, wherein the plurality of output capacitors are arranged on the lower surface of the third printed circuit board.

11. The power module according to claim 9, wherein the first printed circuit board is of a multilayer structure, and the plurality of output capacitors are embedded between a ground layer and an output power layer of the first printed circuit board.

12. The power module according to claim 1, wherein the plurality of power chips are provided with first pulse width modulation signal ports; and
the plurality of power chips are configured to: receive pulse width modulation signals from a controller through the first pulse width modulation signal ports and adjust output voltage according to the pulse width modulation signals.

13. The power module according to claim 12, wherein the plurality of power chips are further provided with at least one of first current signal ports or first temperature signal ports; and
at least one of:
the plurality of power chips are further configured to send detected currents to the controller through the first current signal ports; or
the plurality of power chips are further configured to send detected temperatures to the controller through the first temperature signal ports.

14. The power module according to claim 1, wherein the plurality of output inductors are coupling inductors.

15. The power module according to claim 1, wherein input voltage of the input power source is 5 V.

16. A server, comprising:
a third printed circuit board;
a load, arranged on an upper surface of the third printed circuit board; and
a plurality of power modules, which are spaced apart on a lower surface of the third printed circuit board, wherein the plurality of power modules are connected to the load through a via hole in the third printed circuit board to supply power to the load; wherein
each of the plurality of power modules comprises a plurality of power chips, a plurality of input capacitors, a plurality of output inductors, and a first printed circuit board, wherein
the plurality of power chips are spaced apart on an upper surface of the first printed circuit board, and input ends of the plurality of power chips are connected to an input power source;
the plurality of input capacitors are fixedly arranged at the first printed circuit board; the plurality of input capacitors are connected to the input ends of the plurality of power chips in a one-to-one correspondence manner; and
the plurality of output inductors are stacked with the plurality of power chips in a vertical direction through the first printed circuit board; input ends of the plurality of output inductors are connected to output ends of the plurality of power chips in a one-to-one correspondence manner; output ends of the plurality of output inductors are connected to the load through the via hole in the third printed circuit board to supply power to the load; the plurality of output inductors are located on the lower surface of the third printed circuit board; the load is located on the upper surface of the third printed circuit board; first areas of the plurality of input capacitors, the plurality of power chips, and the plurality of output inductors are smaller than an area of the upper surface of the first printed circuit board; an area of the first printed circuit board is smaller than an area of the third printed circuit board; and the first areas are surface areas of sides, close to the first printed circuit board, of the plurality of input capacitors, the plurality of power chips, and the plurality of output inductors.

17. The server according to claim 16, wherein the server further comprises a first heat dissipation device and a second heat dissipation device;
the first heat dissipation device comprises a first substrate; the first substrate is arranged on one side of the load away from the third printed circuit board;
the second heat dissipation device comprises a second substrate; the second substrate is arranged on one side of a corresponding one of the plurality of power modules away from the third printed circuit board; and the first substrate and the second substrate are connected through a screw and a nut.

18. The server according to claim 17, wherein
the first heat dissipation device further comprises a first heat dissipation fin extending upwards from the first substrate; and
the second heat dissipation device further comprises a second heat dissipation fin connected to the second substrate.

19. The server according to claim 18, wherein the second substrate extends to one side of the third printed circuit board in a horizontal direction, and an extension direction of the second heat dissipation fin is the same as an extension direction of the first heat dissipation fin.

20. The server according to claim 16, wherein the server further comprises a controller;
the controller is provided with a second pulse width modulation signal port; the controller sends a pulse width modulation signal to the plurality of power modules through the second pulse width modulation signal port; and the pulse width modulation signal is configured to adjust output voltages of the plurality of power modules.
